(19) United States
(12) Patent Application Publication
(10) Pub. No.: US 2025/0181069 A1
(43) Pub. Date: Jun. 5, 2025

(54) VEHICLE CONTROL METHOD AND APPARATUS, DEVICE, STORAGE MEDIUM, AND PROGRAM PRODUCT

(71) Applicant: Tencent Technology (Shenzhen) Company Limited, Shenzhen (CN)

(72) Inventor: Yong YANG, Shenzhen (CN)

(73) Assignee: Tencent Technology (Shenzhen) Company Limited, Shenzhen (CN)

(21) Appl. No.: 19/024,044

(22) Filed: Jan. 16, 2025

Related U.S. Application Data
(63) Continuation of application No. PCT/CN2023/127583, filed on Oct. 30, 2023.

(30) Foreign Application Priority Data
Jan. 18, 2023 (CN) 202310118979.1

(51) Int. Cl. G05D 1/224

(52) U.S. Cl. CPC G05D 1/2245

(57) ABSTRACT

A vehicle control method, performed by a remote control system, includes receiving road sensor information transmitted from at least one roadside sensor when a target vehicle is on a road; generating, based on the road sensor information, a scene image depicting a scene in which the target vehicle is located; displaying the scene image through a display screen corresponding to a driving simulator; obtaining driving control operation information generated by the driving simulator in response to a driving control operation, the driving control operation information providing traveling instructions based on the driving control operation information for the target vehicle; and transmitting the driving control operation information to the target vehicle.

### CROSS-REFERENCE TO RELATED APPLICATIONS

The disclosure is a continuation application of International Application No. PCT/CN2023/127583 filed on Oct. 30, 2023, which claims priority to Chinese Patent Application No. 202310118979.1, filed with the China National Intellectual Property Administration on Jan. 18, 2023, the disclosures of each being incorporated by reference herein in their entireties.

### FIELD

The disclosure relates to the field of remote driving technologies, and in particular, to a vehicle control method and apparatus, a device, a non-transitory storage medium, and a computer program product.

### BACKGROUND

With the continuous development of wireless communication technology, the development of remote real-time control has received increasingly more attention in many fields such as remote driving and remote surgery.

In the related art, a remote driving system may be composed of a target vehicle including an on-board camera and a remote control device including a driving simulator. The target vehicle may acquire an image around a vehicle through the on-board camera, and transmit a video image around the vehicle to the remote control device through a mobile communication network (such as the 5^{th} generation mobile communication (5G) network), which is displayed by the remote control device on a display screen of the driving simulator. A remote driver operates the driving simulator based on the video image displayed on the display screen. The remote control device transmits a driving control operation received by the driving simulator to the target vehicle through the mobile communication network, thereby implementing remote driving control of the target vehicle.

However, in the foregoing related art, the target vehicle may transmit the video image to the remote control device through the mobile communication network, which has great impact on safety of the remote driving in a case that communication performance of the target vehicle or a network environment in which the target vehicle is located is poor.

### SUMMARY

According to an aspect of the disclosure, a vehicle control method, performed by a remote control system, includes receiving road sensor information transmitted from at least one roadside sensor when a target vehicle is on a road; generating, based on the road sensor information, a scene image depicting a scene in which the target vehicle is located; displaying the scene image through a display screen corresponding to a driving simulator; obtaining driving control operation information generated by the driving simulator in response to a driving control operation, the driving control operation information providing traveling instructions based on the driving control operation information for the target vehicle; and transmitting the driving control operation information to the target vehicle.

According to an aspect of the disclosure, a vehicle control apparatus, includes at least one memory configured to store computer program code; and at least one processor configured to read the program code and operate as instructed by the program code, the program code including sensor information receiving code configured to cause at least one of the at least one processor to receive road sensor information transmitted from at least one roadside sensor when a target vehicle is on a road; image generation code configured to cause at least one of the at least one processor to generate, based on the road sensor information, a scene image depicting a scene in which the target vehicle is located; image display code configured to cause at least one of the at least one processor to display the scene image through a display screen corresponding to a driving simulator; operation information code configured to cause at least one of the at least one processor to obtain driving control operation information generated by the driving simulator in response to a driving control operation, the driving control operation information providing traveling instructions based on the driving control operation information for the target vehicle; and transmission code configured to cause at least one of the at least one processor to transmit the driving control operation information to the target vehicle.

According to an aspect of the disclosure, a non-transitory computer-readable storage medium, storing computer code which, when executed by at least one processor, causes the at least one processor to at least receive road sensor information transmitted from at least one roadside sensor when a target vehicle is on a road; generate, based on the road sensor information, a scene image depicting a scene in which the target vehicle is located; display the scene image through a display screen corresponding to a driving simulator; obtain driving control operation information generated by the driving simulator in response to a driving control operation, the driving control operation information providing traveling instructions based on the driving control operation information for the target vehicle; and transmit the driving control operation information to the target vehicle.

### BRIEF DESCRIPTION OF THE DRAWINGS

To describe the technical solutions of some embodiments of this disclosure more clearly, the following briefly introduces the accompanying drawings for describing some embodiments. The accompanying drawings in the following description show only some embodiments of the disclosure, and a person of ordinary skill in the art may still derive other drawings from these accompanying drawings without creative efforts. In addition, one of ordinary skill would understand that aspects of some embodiments may be combined together or implemented alone.

FIG. 1 is a schematic diagram of a system according to some embodiments.

FIG. 2 is an architectural diagram of a 5G remote driving product according to some embodiments.

FIG. 3 is a flowchart of a vehicle control method according to some embodiments.

FIG. 4 is a flowchart of a vehicle control method according to some embodiments.

FIG. 5 is a flowchart of a vehicle control method according to some embodiments.

FIG. 6 is a flowchart of a vehicle control method according to some embodiments.

FIG. 7 is a flowchart of a vehicle control method according to some embodiments.

FIG. 8 is a flowchart of a vehicle control method according to some embodiments.

FIG. 9 is a system implementation framework according to some embodiments.

FIG. 10 is another system implementation framework according to some embodiments.

FIG. 11 shows an end-to-end service process.

FIG. 12 is a block diagram of a vehicle control apparatus according to some embodiments.

FIG. 13 is a block diagram of a vehicle control apparatus according to some embodiments.

FIG. 14 is a structural block diagram of a computer device according to some embodiments.

### DESCRIPTION OF EMBODIMENTS

To make the objectives, technical solutions, and advantages of the present disclosure clearer, the following further describes the present disclosure in detail with reference to the accompanying drawings. The described embodiments are not to be construed as a limitation to the present disclosure. All other embodiments obtained by a person of ordinary skill in the art without creative efforts shall fall within the protection scope of the present disclosure.

In the following descriptions, related “some embodiments” describe a subset of all possible embodiments. However, it may be understood that the “some embodiments” may be the same subset or different subsets of all the possible embodiments, and may be combined with each other without conflict. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. For example, the phrase “at least one of A, B, and C” includes within its scope “only A”, “only B”, “only C”, “A and B”, “B and C”, “A and C” and “all of A, B, and C.”

Some embodiments provide a vehicle control method for remote driving in an intelligent traffic system (ITS)/intelligent vehicle infrastructure cooperative system (IVICS), which can provide sensor information of a road surface for remote driving of a target vehicle through a roadside sensor. For ease of understanding, several terms involved in the disclosure are explained below.

### 1) Intelligent Traffic System

It is also referred to as an intelligent transportation system, which is a comprehensive transportation system that ensures safety, improves efficiency, improves an environment, and saves energy formed by effectively and comprehensively applying advanced science and technologies (an information technology, a computer technology, a data communication technology, a sensor technology, an electronic control technology, an automatic control theory, operations research, artificial intelligence, and the like) to transportation, service control, and vehicle manufacturing and enhances connection among vehicles, roads, and users.

### 2) Intelligent Vehicle Infrastructure Cooperative System

It is referred to a vehicle infrastructure cooperative system for short, and is a development direction of the ITS. IVICS is a safe, efficient, and environmentally friendly road traffic system that adopts technologies such as advanced wireless communication and a new generation of Internet to perform an omni-directional vehicle-vehicle and vehicle-infrastructure dynamic real-time information interaction and perform active safety control of vehicles and cooperative road management based on full-space-time dynamic traffic information acquisition and integration, to fully realize effective cooperation among people, vehicles, and roads, ensure traffic safety, and improve traffic efficiency.

### 3) Artificial intelligence (AI)

It involves a theory, a method, a technology, and an application system that use a digital computer or a machine controlled by the digital computer to simulate, extend, and expand human intelligence, perceive an environment, obtain knowledge, and use knowledge to obtain an optimal result. In other words, AI is a comprehensive technology in computer science and attempts to understand the essence of intelligence and produce a new intelligent machine that can react in a manner similar to human intelligence. AI is to study the design principles and implementation methods of various intelligent machines, to enable the machines to have the functions of perception, reasoning, and decision-making.

The AI technology is a comprehensive discipline, and relates to a wide range of fields including both hardware-level technologies and software-level technologies. AI technologies may include technologies such as a sensor, a dedicated AI chip, cloud computing, distributed storage, a big data processing technology, an operating/interaction system, and electromechanical integration. AI software technologies mainly include several major directions such as a computer vision (CV) technology, a speech processing technology, a natural language processing technology, and machine learning/deep learning.

### 4) Computer Vision (CV) Technology

CV is a science that studies how to use a machine to “see”, and furthermore, that uses a camera and a computer to replace human eyes to perform machine vision such as recognition, detection, and measurement on a target, and further perform graphic processing, so that the computer processes the target into an image for human eyes to observe, or an image transmitted to an instrument for detection. As a scientific discipline, CV studies related theories and technologies and attempts to establish an AI system that can obtain information from images or multidimensional data. The CV technology may include technologies such as image processing, image recognition, image semantic understanding, image retrieval, optical character recognition, video processing, video semantic understanding, video content/behavior recognition, three-dimensional object reconstruction, 3D technology, virtual reality, augmented reality, synchronous positioning, and map construction. Frequently used biometric recognition technologies such as facial recognition and fingerprint recognition are further included.

### 5) Machine Learning (ML)

It is an interdisciplinary field, involving a plurality of disciplines such as the theory of probability, statistics, the approximation theory, convex analysis, and the theory of algorithm complexity. ML specializes in studying how a computer simulates or implements a human learning behavior to obtain new knowledge or skills, and reorganize an existing knowledge structure, so as to keep improving performance thereof. ML is the core of AI, is a way to make the computer intelligent, and is applied to various fields of AI. ML and deep learning may include technologies such as an artificial neural network, a belief network, reinforcement learning, transfer learning, inductive learning, and learning from demonstrations.

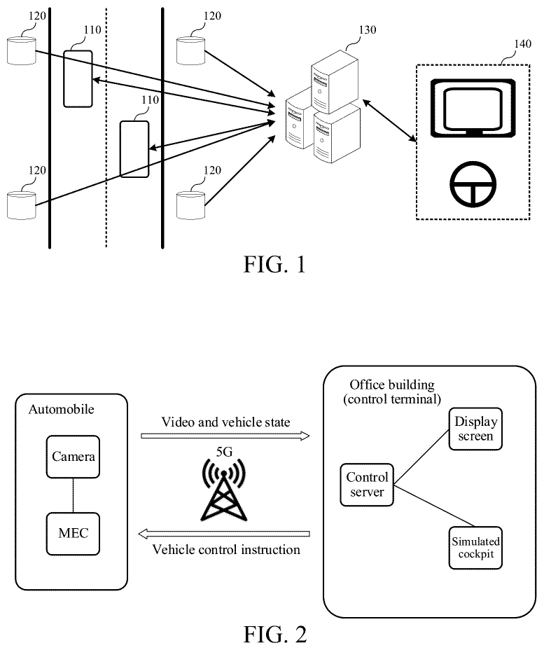

FIG. 1 shows a schematic diagram of a system used by a vehicle control method according to some embodiments. As shown in FIG. 1, the system includes a vehicle 110, a roadside sensor 120, a server 130, and a driving simulator 140.

An automatic control system and a communication assembly may be mounted to the foregoing vehicle 110. The automatic control system may be configured to control the driving of the vehicle 110 through remote instructions received by the communication assembly, including throttle control, brake control, direction control, and the like.

The foregoing roadside sensor 120 may include a sensor assembly, a data processing assembly, a communication assembly, and the like. The roadside sensor may acquire sensor data of a road surface through the sensor assembly. The communication assembly may transmit processed data of the data processing assembly to the server 130.

The foregoing server 130 may be an independent physical server, a server cluster composed of a plurality of physical servers, a distributed system, or a cloud server that provides cloud computing services such as a cloud service, a cloud database, cloud computing, a cloud function, cloud storage, a network service, cloud communication, a middleware service a domain name service, a security service, a content delivery network (CDN), big data, and an AI platform.

The foregoing server 130 may be deployed with an image generation system and generate a scene image through the data transmitted by the roadside sensor 120, and display the scene image in a display screen of the driving simulator 140. For example, the server 130 may be provided with a three-dimensional scene simulation system based on a digital twin, which may generate a scene image of a three-dimensional scene.

The driving simulator 140 may receive a driving control operation of a user. For example, the driving simulator 140 may be a simulated cockpit, including a steering wheel simulator, a brake simulator, a throttle simulator, and the like. Information related to the driving control operation received by the driving simulator 140 is transmitted to the target vehicle by the server 130, and the automatic control system of the target vehicle controls the driving of the target vehicle based on the information related to the driving control operation.

In some embodiments, the system includes at least one vehicle 110, at least one roadside sensor 120, at least one server 130, and at least one driving simulator 140. In some embodiments, a quantity of vehicles 110, a quantity of roadside sensors 120, a quantity of servers 130, and a quantity of driving simulators 140 are not limited.

The foregoing vehicle 110 may be connected to the server 130 through a mobile communication network. The foregoing roadside sensor 120 may be connected to the server 130 through a communication network, and the server 130 may be connected to the driving simulator 140 through a communication network. In some embodiments, the communication network is a wired network or a wireless network.

In some embodiments, the wireless network or the wired network described above uses a standard communication technology and/or protocol. The network is usually the Internet, but may also be any network, including but not limited to a local area network (LAN), a metropolitan area network (MAN), a wide area network (WAN), a mobile, wired, or wireless network, or any combination of a dedicated network or a virtual dedicated network. In some embodiments, technologies and/or formats including hyper text mark-up language (HTML), extensible markup language (XML), and the like are configured for representing data exchanged over the network. In addition, conventional encryption technologies such as a secure socket layer (SSL), transport layer security (TLS), a virtual private network (VPN), and Internet protocol security (IPsec) may be configured for encrypting all or some links. In some embodiments, custom data communication technologies may also be configured for replacing or supplementing the foregoing data communication technologies. This is not limited in the disclosure.

As shown in FIG. 2, in an architectural diagram of a 5G remote driving product, cameras oriented at different angles may be mounted on a vehicle, and videos are acquired, compressed, encoded, and transmitted in real time by a high-performance mobile edge computing (MEC) unit mounted on the vehicle to a control server in a remote office building. Next, a staff member operates a simulated cockpit based on the video of a plurality of cameras presented. A control instruction is transmitted to the MEC of the vehicle through the simulated cockpit, and the MEC of the vehicle controls the vehicle to travel through a controller area network (CAN) bus of an automobile.

According to some embodiments, a plurality of cameras facing different angles may be mounted on the vehicle first, including 5 or even 7 cameras. Next, a high-performance MEC gateway may be deployed in the vehicle, which is configured to acquire a traveling state of the vehicle and the video of the camera, encode and compress the video and then transmit the video to the control server of the office building through a 5G network, and receive a vehicle control instruction transmitted by the control server through the 5G network. Finally, the control server receives the video and then decodes and displays the video, and then a staff member remotely controls the vehicle to travel through the simulated cockpit.

Some embodiments have the following defects.
1) A multi-channel video of the vehicle may be transmitted to a remote control server through a 5G uplink channel. An uplink bandwidth of the 5G network is inherently lower than a downlink bandwidth, which poses a great challenge to a transmission bandwidth of the 5G network. Once a network bandwidth is insufficient, video transmission and remote control of the vehicle are inevitably affected.
2) Since the MEC gateway of the vehicle may acquire, compress, and transmit a video, each vehicle may be equipped with a high-performance MEC device to support processing of the multi-channel video.
3) At night or in severe weather such as rain, snow, and smog, the video cannot effectively identify a traffic status, resulting in impracticability of the remote driving.
4) In some operating scenarios with complex environments, due to limited perspectives of the camera, an operator cannot observe a potential abnormal accident in time, posing a high safety risk, such as sudden intrusion of a pedestrian.

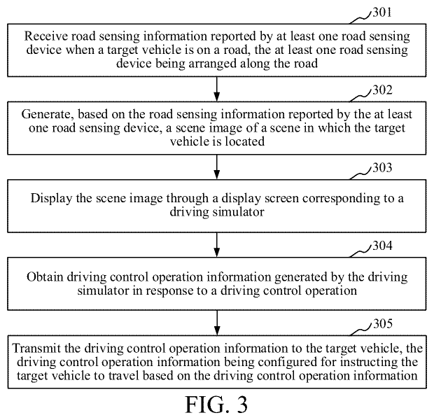

As shown in FIG. 3, in some embodiments, a vehicle control method is provided. The method is performed by a remote control device. The remote control device may be implemented as a cloud server. The cloud server may be the server 130 shown in FIG. 1. As shown in FIG. 3, the vehicle control method includes the following operations.

301: Receive road sensor information reported by at least one roadside sensor when a target vehicle is on a road, the at least one roadside sensor being arranged along the road.

The target vehicle may be a vehicle to be controlled. The target vehicle may be a vehicle controlled by a remote control device. The remote control device may identify the target vehicle. The remote control device may communicate with the target vehicle.

The roadside sensor is a device that monitors a road. The roadside sensor has a sensor. Sensor data may be acquired through the sensor. The roadside sensor is arranged along the road, which may be fixed in a vehicle-restricted area next to the road, or be fixed on the road through a fixed frame erected beside the road.

An image sensor (such as a camera) and a radar sensor (such as a millimeter-wave radar and a lidar) may be arranged in the roadside sensor. The image sensor may be configured to acquire image data, and the radar sensor may be configured to acquire radar point cloud data.

In some embodiments, the roadside sensor may generate road sensor information of the roadside sensor based on the sensor data for the road sensor data, and report the road sensor information to the remote control device.

The road sensor information may include at least one of the image data or the radar point cloud data. The road sensor information may be information generated after processing at least one of the image data or the radar point cloud data.

The roadside sensor may transmit the road sensor information to the remote control device through a wired network. The roadside sensor may transmit the road sensor information to the remote control device through a wireless network, such as a wireless local area network (WLAN) or a mobile communication network. The roadside sensor may also simultaneously transmit the road sensor information to the remote control device through the wired network and the wireless network.

For example, for acquired multi-frame sensor data, the roadside sensor may transmit multi-frame road sensor information corresponding to the multi-frame sensor data to the remote control device through the wired network and the wireless network to improve a reporting rate of the road sensor information.

302: Generate, based on the road sensor information reported by the at least one roadside sensor, a scene image of a scene in which the target vehicle is located.

In some embodiments, the remote control device may generate a scene image around the target vehicle based on the road sensor information reported by the roadside sensor by means of a digital twin technology. The scene image around the target vehicle is the scene image of the scene in which the target vehicle is located.

For example, the remote control device generates a three-dimensional scene in advance. The three-dimensional scene may include fixed parts of the road, such as a road surface and road facilities (a railing, a barrier, a traffic light, and the like), and does not include moving objects on the road (such as a vehicle and a pedestrian). After the road sensor information is received, the foregoing movable object may be added to the three-dimensional scene based on the movable object on the road indicated by the road sensor information. Then, an image of a part corresponding to the target vehicle in the three-dimensional scene after the movable object is added is acquired, so as to generate the scene image around the target vehicle.

In some embodiments, the remote control device may further receive traveling state information transmitted by the target vehicle. When the scene image around the target vehicle is generated based on the road sensor information reported by the at least one roadside sensor, the scene image around the target vehicle may be generated based on the traveling state information transmitted by the target vehicle and the road sensor information reported by at least one roadside sensor.

The traveling state information is information that represents a traveling state of the target vehicle, which may include vehicle position information of the target vehicle, and may further include other information, such as a speed of the target vehicle, a moving direction of the target vehicle, and remaining energy (remaining fuel or remaining electricity) of the target vehicle.

303: Display the scene image through a display screen corresponding to a driving simulator.

The remote control device may include a driving simulator configured to control the target vehicle. The driving simulator configured to control the target vehicle may be a separate device that communicates with the remote control device. The driving simulator is correspondingly provided with the display screen. The display screen may be part of the driving simulator, part of the remote control device, or a stand-alone device. The driving simulator is a device configured to simulate the driving of the vehicle, which may be a simulated cockpit, a keyboard, a handle, or a steering wheel controller.

After the remote control device generates the scene image of the scene in which the target vehicle is located, the scene image is transmitted to the display screen in real time for display, so that the operator of the driving simulator controls the driving simulator based on the scene image, such as acceleration, deceleration, and steering.

304: Obtain driving control operation information generated by the driving simulator in response to a driving control operation.

The driving control operation is an operation triggered by the driving simulator for controlling the target vehicle, which may be a gear setting operation, a steering operation, a whistle operation, an acceleration operation, a deceleration operation, a reversing operation, and the like. The driving control operation information is control information for transmitting to the target vehicle, so as to implement remote control driving by the target vehicle based on the driving control operation information.

The driving control operation information may be an operation instruction for controlling the traveling of the target vehicle, such as a throttle opening instruction, a brake stroke instruction, a steering direction instruction, a steering angle instruction, a light control operation instruction, and the like.

305: Transmit the driving control operation information to the target vehicle, the driving control operation information being configured for instructing the target vehicle to travel based on the driving control operation information.

In some embodiments, after the target vehicle receives the foregoing driving control operation information, the foregoing driving control operation information may be converted into an instruction executable by a vehicle control system, and the converted instruction is executed by the vehicle control system to implement remote driving control of the target vehicle. The remote control device may transmit the driving control operation information to the target vehicle through a relay of the roadside sensor.

Based on the above, in the solutions shown in some embodiments, the road sensor information is acquired by the roadside sensor arranged along the road. The road sensor information is transmitted to the remote control device. The remote control device generates the scene image around the target vehicle based on the road sensor information, and displays the scene image in the display screen corresponding to the driving simulator, and transmits the information of the driving control operation received by the driving simulator to the target vehicle to implement the remote driving. The target vehicle may not upload the video image for controlling the target vehicle, and the uploading of the road sensor information is not restricted by the wireless network environment. Therefore, a communication problem between the target vehicle and the remote control device may be prevented from affecting the remote driving, thereby improving safety of the remote driving.

In some embodiments, the road sensor information is generated based on sensor data acquired by the roadside sensor, and the sensor data includes at least one of image data or radar point cloud data.

An image sensor (such as a camera) and a radar sensor (such as a millimeter-wave radar and a lidar) may be arranged in the roadside sensor. The image sensor may be configured to acquire image data, and the radar sensor may be configured to acquire radar point cloud data.

In some embodiments, the image data may provide information to generate the scene image from a visual perspective. The radar point cloud data may provide information to generate the scene image from a radar detection angle. In other words, the sensor data includes the image data and the radar point cloud data, which can provide information to generate the scene image from two dimensions, so as to provide more comprehensive and accurate information for the remote driving and ensure the driving safety.

In some embodiments, the generating, based on the road sensor information reported by the at least one roadside sensor, a scene image of a scene in which the target vehicle is located includes: determining, from the road sensor information reported by the at least one roadside sensor, sensor information related to the target vehicle; and generating, based on the sensor information related to the target vehicle, the scene image of the scene in which the target vehicle is located.

In some embodiments, the remote control device may receive the road sensor information reported by a plurality of roadside sensors in real time. Some of these road sensor information may not include relevant information about the road surface around the target vehicle. In this case, to save a computing resource and improve a utilization rate of the computing resource, the remote control device can screen, for the road sensor information that may include relevant information about the road surface around the target vehicle, the road sensor information reported by the at least one roadside sensor.

In some embodiments, the vehicle control method further includes: receiving vehicle position information reported by the target vehicle. The determining, from the road sensor information reported by the at least one roadside sensor, sensor information related to the vehicle includes: screening, based on the vehicle position information, the road sensor information reported by the at least one roadside sensor, to obtain the sensor information related to the vehicle.

In some embodiments, the remote control device may further receive the traveling state information reported by the target vehicle. The traveling state information includes the vehicle position information of the target vehicle. When the sensor information related to the target vehicle is determined from the road sensor information reported by the at least one roadside sensor, the remote control device may determine the sensor information related to the target vehicle from the road sensor information reported by the at least one roadside sensor based on the vehicle position information.

In some embodiments, the target vehicle can report the traveling state information to the remote control device in real time. The traveling state information includes the vehicle position information of the target vehicle.

In some embodiments, the road sensor information includes identification information of a candidate vehicle within a specified range around the roadside sensor, the candidate vehicle being a vehicle that supports remote control. The determining, from the road sensor information reported by the at least one roadside sensor, sensor information related to the vehicle includes: screening, for road sensor information including identification information of the target vehicle, the road sensor information reported by the at least one roadside sensor, to obtain the sensor information related to the vehicle.

The vehicle position information of the foregoing target vehicle may include position information of the target vehicle, such as geographical coordinates of the target vehicle. The vehicle position information of the foregoing target vehicle may further include the position information of the specified device around the target vehicle. For example, device identification or geographic coordinates of the roadside sensor closest to the target vehicle is included.

In some embodiments, the foregoing traveling state information may further include other information, such as the speed of the target vehicle, the moving direction of the target vehicle, and the remaining energy (the remaining fuel or the remaining electricity) of the target vehicle.

In some embodiments, when the remote control device determines the sensor information related to the target vehicle from the road sensor information reported by the at least one roadside sensor based on the vehicle position information, a distance between the vehicle position information and various roadside sensors can be calculated. Road sensor information reported by the roadside sensor whose distance is less than a first distance threshold is determined as the sensor information related to the vehicle.

In some embodiments, in a case that the foregoing road sensor information includes a road surface object on the road and object information of the road surface object, the roadside sensor may further add identification information of the candidate vehicle to the road sensor information for the candidate vehicle in the road surface object.

The foregoing candidate vehicle may be determined by wireless communication between the roadside sensor and the candidate vehicle. For example, the candidate vehicle that supports remote control (for example, an automatic control system is mounted, or a remote driving function of the automatic control system is turned on) may communicate with a surrounding roadside sensor by means of a wireless communication mode. In the process, the roadside sensor may have identification information of a surrounding candidate vehicle communicating with the roadside sensor in real time recorded, and have the identification information of the recorded candidate vehicle recorded in the road sensor information corresponding to currently acquired sensor data.

After receiving the foregoing road sensor information, the remote control device may read the identification information of the candidate vehicle included in the road sensor information and compare the identification information of the candidate vehicle with the identification information of the target vehicle. If the road sensor information includes the identification information of the target vehicle, it may be determined that the road sensor information is transmitted by a roadside sensor close to the target vehicle. In this case, the remote control device may determine the road sensor information as the sensor information related to the target vehicle corresponding to the target vehicle.

In some embodiments, the generating, based on the road sensor information reported by the at least one roadside sensor, a scene image of a scene in which the target vehicle is located includes: obtaining a specified perspective; and generating, based on the specified perspective and the road sensor information reported by the at least one roadside sensor, a scene image of the scene in which the target vehicle is located from the specified perspective.

The specified perspective may be a preset perspective or a perspective specified by a user through the driving simulator.

In some embodiments, the specified perspective includes at least one of a driver's seat perspective or an external perspective, and the external perspective includes at least one of a third-person perspective and a top-down perspective. The third-person perspective is a perspective of the vehicle from a perspective of someone outside the vehicle. The top-down perspective is a perspective of the vehicle from above the vehicle in the air.

In the foregoing driver's seat perspective, the scene image displayed on the display screen is closer to a real scene seen by the operator sitting in a driving position of the target vehicle, which can simulate a real driving situation of the user and meet a real driving habit.

In the foregoing external perspective, the scene image displayed by the display screen can display a complete scene around the target vehicle more clearly, so that the operator can obtain more information, thereby making the driving control operations more accurately.

In some embodiments, the vehicle control method further includes: Obtaining an adjusted perspective obtained by adjusting the specified perspective by the driving simulator, the adjustment being triggered by the driving simulator in response to a perspective adjustment operation; generating, based on the adjusted perspective and the road sensor information reported by the at least one roadside sensor, a scene image of the scene in which the target vehicle is located under the adjusted perspective; and displaying the scene image under the adjusted perspective on the display screen.

A perspective adjustment assembly may be arranged in the driving simulator, such as a perspective adjustment button, a perspective adjustment control, and a perspective switch button. The operator of the driving simulator may switch or adjust the perspective corresponding to the scene image displayed on the display screen through the foregoing perspective adjustment assembly. Correspondingly, the remote control device can adjust the specified perspective based on the foregoing perspective adjustment operation, and generate the scene image around the target vehicle based on the adjusted specified perspective.

In some embodiments, the perspective may be adjusted to provide the scene image to further ensure safety of the remote driving.

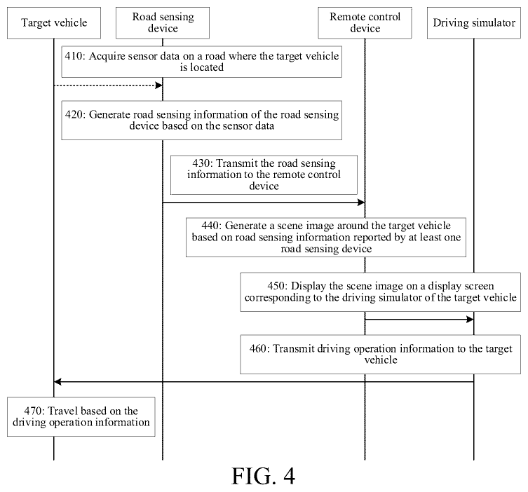

FIG. 4 is a flowchart of a vehicle control method according to some embodiments. The method is interactively performed by a remote control device, a roadside sensor, and a target vehicle. The remote control device may be implemented as a cloud server. The cloud server may be the server 130 shown in FIG. 1. The foregoing roadside sensor may be the roadside sensor 120 shown in FIG. 1. The foregoing target vehicle may be the vehicle 110 shown in FIG. 1. As shown in FIG. 4, the vehicle control method includes the following operations.

Operation 410: The roadside sensor acquires sensor data on a road where the target vehicle is located, the sensor data including at least one of image data and radar point cloud data, the roadside sensor being a sensor device arranged along the road where the target vehicle is located.

An image sensor (such as a camera) and a radar sensor (such as a millimeter-wave radar and a lidar) may be arranged in the foregoing roadside sensor. The image sensor may be configured to acquire image data, and the radar sensor may be configured to acquire radar point cloud data.

Operation 420: The roadside sensor generates road sensor information of the roadside sensor based on the sensor data.

The foregoing road sensor information may include at least one of the image data and the radar point cloud data.

The foregoing road sensor information may further be information generated after processing at least one of the image data and the radar point cloud data.

Operation 430: The roadside sensor transmits the road sensor information to the remote control device, the remote control device being configured to receive the road sensor information reported by the at least one roadside sensor.

In some embodiments, the roadside sensor may transmit the road sensor information to the remote control device through a wired network.

In some embodiments, the roadside sensor may transmit the road sensor information to the remote control device through a wireless network, such as a WLAN or a mobile communication network.

In some embodiments, the roadside sensor may also simultaneously transmit the road sensor information to the remote control device through the wired network and the wireless network.

For example, for acquired multi-frame sensor data, the roadside sensor may transmit multi-frame road sensor information corresponding to the multi-frame sensor data to the remote control device through the wired network and the wireless network to improve a reporting rate of the road sensor information.

Operation 440: The remote control device generates a scene image around the target vehicle based on the road sensor information reported by the at least one roadside sensor.

In some embodiments, the remote control device may generate the scene image around the target vehicle based on the road sensor information reported by the roadside sensor by means of a digital twin technology.

For example, the remote control device generates a three-dimensional scene in advance. The three-dimensional scene may include fixed parts of the road, such as a road surface and road facilities (a railing, a barrier, a traffic light, and the like), and does not include moving objects on the road (such as a vehicle and a pedestrian). After the road sensor information is received, the foregoing movable object may be added to the three-dimensional scene based on the movable object on the road indicated by the road sensor information. Then, an image of a part corresponding to the target vehicle in the three-dimensional scene after the movable object is added is acquired, so as to generate the scene image around the target vehicle.

In some embodiments, the remote control device may further receive traveling state information transmitted by the target vehicle. When the scene image around the target vehicle is generated based on the road sensor information reported by the at least one roadside sensor, the scene image around the target vehicle may be generated based on the traveling state information transmitted by the target vehicle and the road sensor information reported by at least one roadside sensor.

Operation 450: The remote control device displays the scene image on a display screen corresponding to a driving simulator of the target vehicle.

In some embodiments, the remote control device may include the driving simulator of the target vehicle, which is provided with a corresponding display screen. After the remote control device generates the scene image around the target vehicle, the scene image is transmitted to the display screen in real time for display, so that the operator of the driving simulator controls the driving simulator based on the scene image, such as acceleration, deceleration, and steering.

Operation 460: The remote control device transmits driving control operation information to the target vehicle, and the target vehicle receives the driving control operation information, the driving control operation information being configured for indicating a driving control operation received by the driving simulator.

In some embodiments, the remote control device may transmit the foregoing driving control operation information to the target vehicle through the mobile communication network.

The foregoing driving control operation information may be an operation instruction for controlling the traveling of the target vehicle, such as a throttle opening instruction, a brake stroke instruction, a steering direction instruction, a steering angle instruction, a light control operation instruction, and the like.

Operation 470: The target vehicle travels based on the driving control operation information.

In some embodiments, after the target vehicle receives the foregoing driving control operation information, the foregoing driving control operation information may be converted into an instruction executable by a vehicle control system, and the converted instruction is executed by the vehicle control system to implement remote driving control of the target vehicle.

Based on the above, in the solutions shown in some embodiments, the roadside sensor arranged along the road acquires at least one of the image data of the road and the radar point cloud data, generates the road sensor information, and transmits the road sensor information to the remote control device. The remote control device generates the scene image around the target vehicle based on the road sensor information, displays the scene image in the display screen corresponding to the driving simulator, and transmits the information of the driving control operation received by the driving simulator to the target vehicle to implement the remote driving. In some embodiments, the target vehicle may not upload the video image, and the uploading of the road sensor information is not restricted by the wireless network environment. Therefore, a communication problem between the target vehicle and the remote control device may be prevented from affecting the remote driving, thereby improving safety of the remote driving.

Based on some embodiments provided in some embodiments illustrated in FIG. 4, a safer and more reliable 5G remote driving or remote control product may be implemented in the disclosure. 1) A high uplink bandwidth requirement of a convectional 5G remote control solution for a 5G network may be satisfied; 2) In the disclosure, a problem that excessively much hardware is deployed in the vehicle, resulting in excessively high real-time complexity and implementation costs of an entire system may be resolved; 3) In the disclosure, a problem that a video cannot effectively identify an environmental condition in severe weather such as rain, snow, and smog or at night may be solved; 4) In the disclosure, safety of 5G remote control and remote operation may be further enhanced by providing multi-angle environmental observation and providing a video from perspectives outside the vehicle.

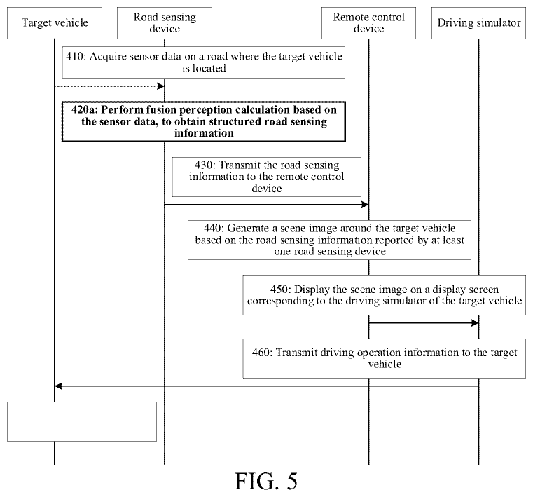

FIG. 5 is a flowchart of a vehicle control method according to some embodiments. The method is interactively performed by a remote control device, a roadside sensor, and a target vehicle. The remote control device may be implemented as a cloud server. The cloud server may be the server 130 shown in FIG. 1. The foregoing roadside sensor may be the roadside sensor 120 shown in FIG. 1. The foregoing target vehicle may be the vehicle 110 shown in FIG. 1. As shown in FIG. 5, operation 420 in some embodiments illustrated in FIG. 4 may be replaced with operation 420a.

Operation 420a: The roadside sensor performs fusion perception calculation based on the sensor data, to obtain structured road sensor information.

The foregoing structured road sensor information includes a road surface object on the road and object information of the road surface object, the road surface object includes at least one of a vehicle, a pedestrian, and a road facility, and the object information includes at least one of a position, a speed, and a moving direction.

In some embodiments, the remote control device may generate the scene image around the target vehicle based on the road surface object on the road and the object information of the road surface object. First processing of the sensor data may obtain the road surface object on the road and the object information of the road surface object. However, the foregoing process of processing the sensor data to obtain the road surface object on the road and the object information of the road surface object may consume many processing resources. If the foregoing process is performed by a remote control device side, subsequent resources for generating the scene image around the target vehicle based on the road surface object on the road and the object information of the road surface object are occupied, resulting in poor efficiency of generating the scene image, and affecting quantities of driving simulators and roadside sensors to which the remote control device is connected.

To reduce a calculation for generating the scene image by the remote control device and improve the efficiency of generating the scene image by the remote control device, in some embodiments, the foregoing process of processing the sensor data to obtain the road surface object on the road and the object information of the road surface object may be performed by the roadside sensor. Since a plurality of roadside sensors are included and each roadside sensor only may process the sensor data acquired by the roadside sensor, resource-consuming calculations (e.g., calculations related to the processing of the sensor data to obtain the road surface object on the road and the object information of the road surface object) may be distributed through distributed edge processing for performance outside the remote control device, thereby improving the efficiency of generating the scene image and increasing the quantities of the driving simulators and the roadside sensors to which the remote control device is connected.

In addition, if the foregoing process is performed by the remote control device side, a large number of communication resources between the remote control device and the roadside sensor are occupied, which has a relatively high requirement for a bandwidth between the remote control device and the roadside sensor. In addition, a large amount of sensor data may cause a high latency in the generation of the scene image, and affects safety of the remote driving control. However, in the solution provided in some embodiments, the resource-consuming calculations (e.g., the calculations related to the processing of the sensor data to obtain the road surface object on the road and the object information of the road surface object) may be distributed for performance outside the remote control device. The roadside sensor only may transmit and process the obtained road surface object on the road and the object information of the road surface object, which can greatly reduce an amount of data transmitted between the remote control device and the roadside sensor, can reduce the bandwidth requirement between the remote control device and the roadside sensor, ensure a low latency of the generation of the scene image, and improve the safety of the remote driving control.

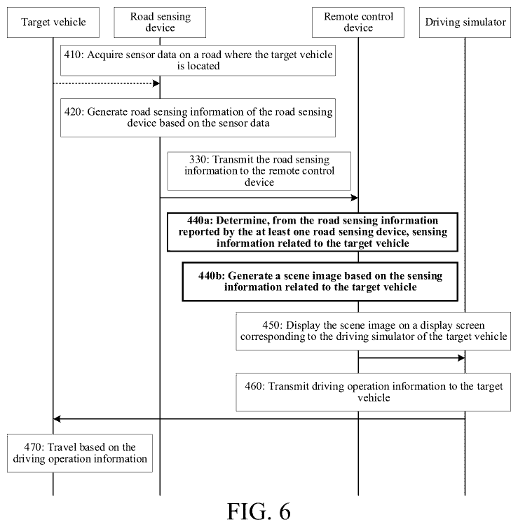

FIG. 6 is a flowchart of a vehicle control method according to some embodiments. The method is interactively performed by a remote control device, a roadside sensor, and a target vehicle. The remote control device may be implemented as a cloud server. The cloud server may be the server 130 shown in FIG. 1. The foregoing roadside sensor may be the roadside sensor 120 shown in FIG. 1. The foregoing target vehicle may be the vehicle 110 shown in FIG. 1. As shown in FIG. 6, operation 440 in some embodiments illustrated in FIG. 4 may be replaced with operation 440a and operation 440b.

Operation 440a: The remote control device determines, from the road sensor information reported by the at least one roadside sensor, sensor information related to the target vehicle.

In some embodiments, the remote control device may simultaneously receive the road sensor information reported by a plurality of roadside sensors in real time. Some of these road sensor information may not include relevant information about the road surface around the target vehicle. In this case, to save a computing resource and improve a utilization rate of the computing resource, the remote control device can screen, for the road sensor information that may include relevant information about the road surface around the target vehicle, the road sensor information reported by the at least one roadside sensor.

In some embodiments, the remote control device may further receive the traveling state information reported by the target vehicle. The traveling state information includes the vehicle position information of the target vehicle. When the sensor information related to the target vehicle is determined from the road sensor information reported by the at least one roadside sensor, the remote control device may determine the sensor information related to the target vehicle from the road sensor information reported by the at least one roadside sensor based on the vehicle position information.

In some embodiments, the target vehicle can report the traveling state information to the remote control device in real time. The traveling state information includes the vehicle position information of the target vehicle.

The vehicle position information of the foregoing target vehicle may include position information of the target vehicle, such as geographical coordinates of the target vehicle. The vehicle position information of the foregoing target vehicle may further include the position information of the specified device around the target vehicle. For example, device identification or geographic coordinates of the roadside sensor closest to the target vehicle is included.

In some embodiments, the foregoing traveling state information may further include other information, such as the speed of the target vehicle, the moving direction of the target vehicle, and the remaining energy (the remaining fuel or the remaining electricity) of the target vehicle.

In some embodiments, when the remote control device determines the sensor information related to the target vehicle from the road sensor information reported by the at least one roadside sensor based on the vehicle position information, a distance between the vehicle position information and various roadside sensors can be calculated. Road sensor information reported by the roadside sensor whose distance is less than a first distance threshold is determined as the sensor information related to the vehicle.

In some embodiments, the road sensor information includes identification information of a candidate vehicle within a specified range around the roadside sensor, the candidate vehicle being a vehicle that supports remote control. When the sensor information related to the target vehicle is determined from the road sensor information reported by the at least one roadside sensor, the remote control device may obtain the road sensor information of the target vehicle from the road sensor information reported by at least one roadside sensor as the sensor information related to the vehicle.

For example, in a case that the foregoing road sensor information includes a road surface object on the road and object information of the road surface object, the roadside sensor may further add identification information of the candidate vehicle to the road sensor information for the candidate vehicle in the road surface object.

The foregoing candidate vehicle may be determined by wireless communication between the roadside sensor and the candidate vehicle. For example, the candidate vehicle that supports remote control (for example, an automatic control system is mounted, or a remote driving function of the automatic control system is turned on) may communicate with a surrounding roadside sensor by means of a wireless communication mode. In the process, the roadside sensor may have identification information of a surrounding candidate vehicle communicating with the roadside sensor in real time recorded, and have the identification information of the recorded candidate vehicle recorded in the road sensor information corresponding to currently acquired sensor data.

After receiving the foregoing road sensor information, the remote control device may read the identification information of the candidate vehicle included in the road sensor information and compare the identification information of the candidate vehicle with the identification information of the target vehicle. If the road sensor information includes the identification information of the target vehicle, it may be determined that the road sensor information is transmitted by a roadside sensor close to the target vehicle. In this case, the remote control device may determine the road sensor information as the sensor information related to the target vehicle corresponding to the target vehicle.

Operation 440b: The remote control device generates the scene image based on the sensor information related to the vehicle.

In some embodiments, the remote control device only may generate the scene image around the target vehicle based on the sensor information related to the vehicle, and may not process all the road sensor information for the target vehicle. In a road section with fewer vehicles having the remote driving function, the calculation to generate the scene image can be greatly reduced, thereby improving the efficiency of generating the scene image.

In addition, in the solutions shown in some embodiments, in a road section with a plurality of vehicles having the remote driving function, the remote control device may also uniformly generate a three-dimensional scene with the movable objects based on the road sensor information uploaded by all the roadside sensors on the road section. Then, based on a uniformly generated three-dimensional scene, the scene images are respectively generated for each vehicle having the remote driving function in the three-dimensional scene. The three-dimensional scene is not to respectively generate for each vehicle having the remote driving function. Therefore, in the road section with the plurality of vehicles having the remote driving function, the calculation to generate the scene image is reduced, and the efficiency of generating the scene image is improved.

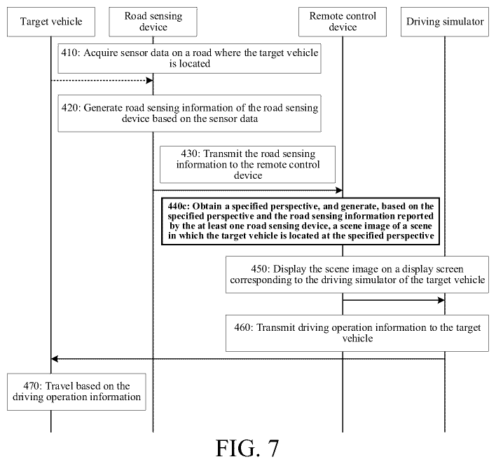

FIG. 7 is a flowchart of a vehicle control method according to some embodiments. The method is interactively performed by a remote control device, a roadside sensor, and a target vehicle. The remote control device may be implemented as a cloud server. The cloud server may be the server 130 shown in FIG. 1. The foregoing roadside sensor may be the roadside sensor 120 shown in FIG. 1. The foregoing target vehicle may be the vehicle 110 shown in FIG. 1. As shown in FIG. 7, operation 440 in some embodiments illustrated in FIG. 4 may be replaced with operation 440c.

Operation 440c: The remote control device obtains a specified perspective, and generates, based on the specified perspective and the road sensor information reported by the at least one roadside sensor, a scene image of the scene in which the target vehicle is located from the specified perspective.

The specified perspective includes at least one of the following perspectives:
at least one of a driver's seat perspective or an external perspective, and the external perspective includes at least one of a third-person perspective and a top-down perspective.

In the foregoing driver's seat perspective, the scene image displayed on the display screen is closer to a real scene seen by the operator sitting in a driving position of the target vehicle, which can simulate a real driving situation of the user and meet a real driving habit.

In the foregoing external perspective, the scene image displayed by the display screen can display a complete scene around the target vehicle more clearly, so that the operator can obtain more information, thereby making the driving control operations more accurately.

In some embodiments, the method may further include the following operations.

The remote control device obtains a perspective adjustment operation received by the driving simulator; and adjusts the specified perspective based on the perspective adjustment operation.

In some embodiments, a perspective adjustment assembly may be arranged in the driving simulator, such as a perspective adjustment button, a perspective adjustment control, and a perspective switch button. The operator of the driving simulator may switch or adjust the perspective corresponding to the scene image displayed on the display screen through the foregoing perspective adjustment assembly. Correspondingly, the remote control device can adjust the specified perspective based on the foregoing perspective adjustment operation, and generate the scene image around the target vehicle based on the adjusted specified perspective.

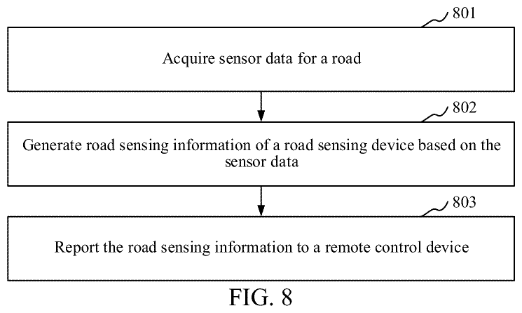

As shown in FIG. 8, in some embodiments, a vehicle control method is provided, performed by a roadside sensor, the roadside sensor being arranged along a road on which a target vehicle is located. The method includes the following operations.

Operation 801: Acquire sensor data for the road.

Operation 802: Generate road sensor information of the roadside sensor based on the sensor data.

Operation 803: Report the road sensor information to a remote control device.

The remote control device is configured to: generate, based on road sensor information reported by at least one roadside sensor, a scene image of a scene in which the target vehicle is located, display the scene image through a display screen corresponding to a driving simulator, obtain driving control operation information generated by the driving simulator in response to a driving control operation, and transmit the driving control operation information to the target vehicle, the driving control operation information being configured for instructing the target vehicle to travel based on the driving control operation information.

In some embodiments, the road sensor information includes identification information of a candidate vehicle within a specified range around the roadside sensor, the candidate vehicle being a vehicle that supports remote control, the remote control device being further configured to: screen, for road sensor information including identification information of the target vehicle, the road sensor information reported by the at least one roadside sensor, to obtain the sensor information related to the vehicle, and generate, based on the sensor information related to the target vehicle, the scene image of the scene in which the target vehicle is located.

In some embodiments, the generating road sensor information of the roadside sensor based on the sensor data includes: performing fusion perception calculation based on the sensor data, to obtain structured road sensor information, the structured road sensor information including a road surface object on the road and object information of the road surface object. The road surface object includes at least one of a vehicle, a pedestrian, and a road facility. The object information includes at least one of a position, a speed, and a moving direction.

For FIG. 8 and the embodiment based on FIG. 8, reference is made to corresponding embodiments illustrated in FIG. 3 to FIG. 7.

The disclosure further provides a vehicle control system, the system including a roadside sensor and a remote control device.

The roadside sensor is configured to: when a target vehicle is on a road, acquire sensor data for the road, generate road sensor information of the roadside sensor based on the sensor data, and report the road sensor information to the remote control device.

The remote control device is configured to: receive road sensor information reported by the at least one roadside sensor, and the at least one roadside sensor being arranged along the road; generate, based on the road sensor information reported by the at least one roadside sensor, a scene image of a scene in which the target vehicle is located; display the scene image through a display screen corresponding to a driving simulator; obtain driving control operation information generated by the driving simulator in response to a driving control operation; and transmit the driving control operation information to the target vehicle, the driving control operation information being configured for instructing the target vehicle to travel based on the driving control operation information.

In some embodiments, the road sensor information includes identification information of a candidate vehicle within a specified range around the roadside sensor, the candidate vehicle being a vehicle that supports remote control, the remote control device being further configured to: screen, for road sensor information including identification information of the target vehicle, the road sensor information reported by the at least one roadside sensor, to obtain the sensor information related to the vehicle, and generate, based on the sensor information related to the target vehicle, the scene image of the scene in which the target vehicle is located.

In some embodiments, the roadside sensor is further configured to perform fusion perception calculation based on the sensor data, to obtain structured road sensor information, the structured road sensor information including a road surface object on the road and object information of the road surface object. The road surface object includes at least one of a vehicle, a pedestrian, and a road facility. The object information includes at least one of a position, a speed, and a moving direction.

In some embodiments, the roadside sensor is a sensor device, the road sensor information being generated based on sensor data acquired by the roadside sensor, the sensor data including at least one of image data or radar point cloud data.

In some embodiments, the remote control device is further configured to: determine, from the road sensor information reported by the at least one roadside sensor, sensor information related to the target vehicle; and generate, based on the sensor information related to the target vehicle, the scene image of the scene in which the target vehicle is located.

In some embodiments, the remote control device is further configured to: receive vehicle position information reported by the target vehicle; and screen, based on the vehicle position information, the road sensor information reported by the at least one roadside sensor, to obtain the sensor information related to the vehicle.

In some embodiments, the road sensor information includes identification information of a candidate vehicle within a specified range around the roadside sensor, the candidate vehicle being a vehicle that supports remote control. The remote control device is further configured to screen, for road sensor information including identification information of the target vehicle, the road sensor information reported by the at least one roadside sensor, to obtain the sensor information related to the vehicle.

In some embodiments, the remote control device is further configured to: obtain a specified perspective; and generate, based on the specified perspective and the road sensor information reported by the at least one roadside sensor, a scene image of the scene in which the target vehicle is located from the specified perspective.

In some embodiments, the specified perspective includes at least one of a driver's seat perspective or an external perspective, and the external perspective includes at least one of a third-person perspective and a top-down perspective.

In some embodiments, the remote control device is further configured to: obtain an adjusted perspective obtained by adjusting the specified perspective by the driving simulator, the adjustment being triggered by the driving simulator in response to a perspective adjustment operation; generate, based on the adjusted perspective and the road sensor information reported by the at least one roadside sensor, a scene image of the scene in which the target vehicle is located under the adjusted perspective; and display the scene image under the adjusted perspective on the display screen.

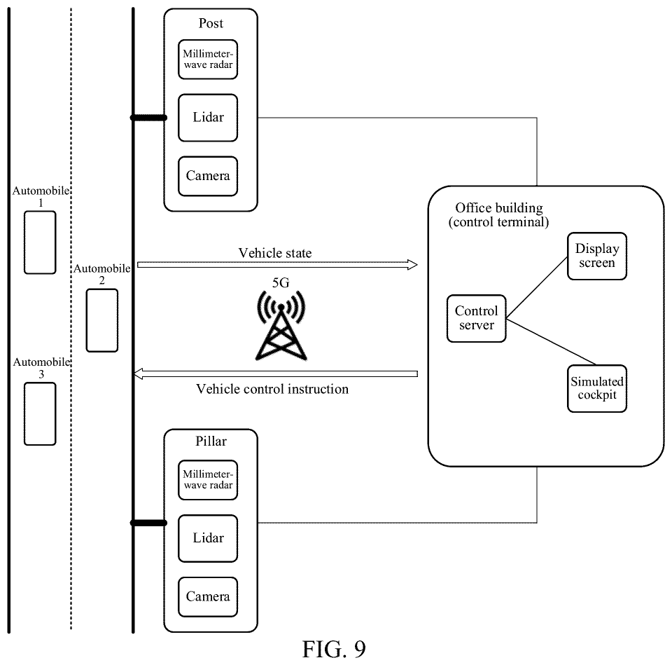

The solutions provided in the foregoing embodiments of the disclosure are described below by using an application scene as an example. A system implementation framework of the disclosure is shown in FIG. 9. A post and an MEC are deployed on a roadside and spaced apart from each other by a certain distance. The post and the MEC form the foregoing roadside sensor. A millimeter-wave radar, a lidar, and a camera are mounted to the post. Acquired data (video data, laser point cloud data, or the like) is outputted to the MEC. The MEC performs fusion perception calculation. A calculation result is transmitted to a control server (corresponding to the foregoing remote control device) in an office building in a form of structured data through a wired network or a 5G network. A real-time digital twin engine is deployed in the control server to perform real-time multi-angle rendering based on environmental data acquired beforehand and state data transmitted from the vehicle through the 5G network and output a rendered video to the display screen for display. An operator remotely operates through a simulated cockpit based on a multi-angle real-time digital twin video on the display screen. An operation instruction is transmitted to an automobile on a road by the 5G network.

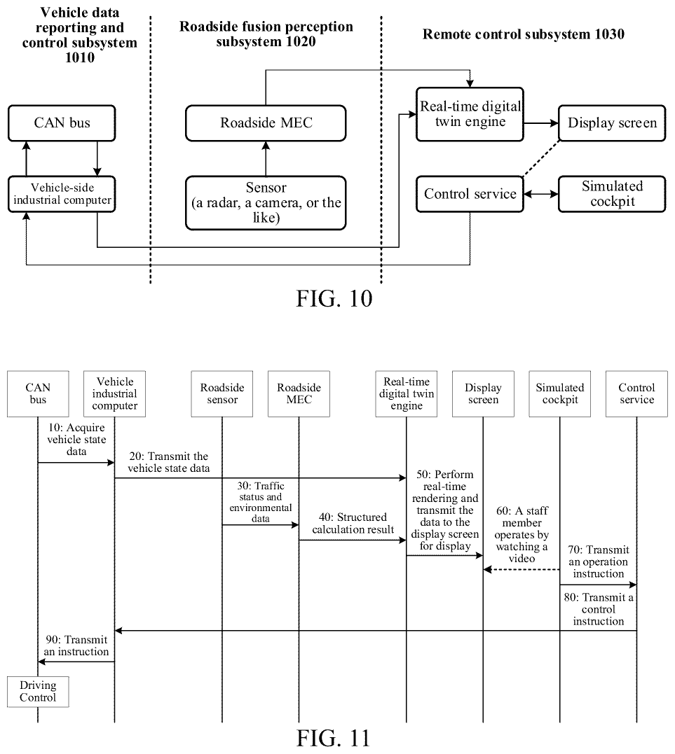

Another system implementation framework of the disclosure is shown in FIG. 10. The system is composed of a vehicle data reporting and control subsystem 1010, a roadside fusion perception subsystem 1020, and a remote control subsystem 1030. Functions of each subsystem are as follows.
1) Vehicle data reporting and control subsystem 1010. In an upward direction, it is configured to acquire state data of a vehicle and transmit the state data to a real-time digital twin engine at a remote end through a 5G network. In a downward direction, it is configured to receive a control instruction issued by a remote control service and transmit control instruction to a vehicle through a CAN bus of an automobile, so as to control the automobile. A lightweight industrial computer may be mounted to a vehicle control subsystem. The industrial computer runs a control service, which is configured for interacting with the CAN bus of the automobile.
2) Roadside fusion perception subsystem 1020. It includes a sensor such as a camera and a radar deployed on a roadside and a roadside MEC. The sensor acquires a video and radar point cloud data of a traffic status and an environment. Then, the roadside MEC performs fusion perception calculation. A calculation result is structured perception data, including an automobile, a pedestrian, a traffic lights, or another object on a road, and positions, speeds, and directions thereof. The structured data is transmitted by the MEC over the network to a remote real-time digital twin engine.
3) Remote control subsystem 1030 It includes a real-time digital twin engine, a display screen, a control service, and a simulated cockpit. The real-time digital twin engine is configured to perform multi-angle rendering based on a reconstructed three-dimensional digital base and a real-time traffic status and environmental data outputted from a roadside sensor subsystem and output a rendered video to the display screen for display. A remote operator operates through the simulated cockpit. The operation instruction is transmitted to the industrial computer of the vehicle from the 5G network through the control service.

The simulated cockpit in the disclosure may be a simulated steering wheel with a universal serial bus (USB) connector or an actual simulated vehicle. An analog square disk of the USB is usually provided with a dynamic link library, which is integrated by a control service area. However, for a simulated vehicle, a control signal may be acquired by docking with a CAN bus thereof.

An end-to-end service process of the disclosure is described in detail below. As shown in FIG. 11, some embodiments are described as follows.
10: An industrial computer of a vehicle acquires vehicle state data through a CAN bus of an automobile.
20: The vehicle state data is transmitted to a real-time digital twin engine in a remote control room through a 5G network.
30: A roadside sensor simultaneously acquires a traffic status and environmental data, and transmits the traffic status and the environmental data to a roadside MEC.
40: The roadside MEC performs fusion perception calculation, and obtains a structured calculation result of the traffic status and the environment, which are transmitted to the real-time digital twin engine in the remote control room through a network.
50: The real-time digital twin engine performs real-time rendering by combining reconstructed three-dimensional environment digital base, the vehicle state data, and roadside fusion perception data that are acquired, and transmits the data to the display screen for display.
60: A staff member of the simulated cockpit operates by watching a video on the display screen.
70: Transmit the operation instruction of the simulated cockpit to the control service.
80: The control service transmits the control instruction to the industrial computer of the vehicle through the 5G network.
90: The industrial computer of the vehicle transmits an instruction to the automobile through the CAN bus to control the automobile to drive.

In the disclosure, real-time rendering of the digital twin may adopt cloud rendering or adopt end rendering. Moreover, in the disclosure, data of roadside fusion perception may be transmitted to the remote control room based on a wired network, or may be transmitted back through the 5G network. In addition, the simulated cockpit used in the disclosure may have a variety of travels, including but not limited to a simulated steering wheel with a USB connector, and an actual simulated vehicle. A connection thereof may be realized through USB interface-based, serial port-based, or parallel port-based communication, CAN bus-based connection, or another Ethernet-based connection manner. Similarly, in the vehicle, the industrial computer may be directly connected to the CAN bus to control the vehicle, or may be connected through an interface provided by third-party autonomous driving software. Finally, the remote driving in the disclosure is not only applicable to the remote control of the automobile, but also to another mechanical device, such as an excavator and a mining truck.

A method for implementing a 5G remote driving product based on a real-time digital twin is implemented through the disclosure. Different from an existing solution based on 5G video transmission, the method is a brand new 5G remote control solution based on a real-time digital twin. A perceptual computing service is deployed on a roadside to perform analysis and calculation for a traffic status and an environment in real time. Then roadside perception data is transmitted to a cockpit in an office through a low-latency 5G network. However, a cockpit side renders and presents a panoramic driving state and the traffic status and environment of a current vehicle based on the real-time digital twin technology, so that a staff member is allowed to perform remote driving around the clock. In the solution, the real-time digital twin technology is adopted to display a real-time traffic status and environmental information of vehicle operations, which may provide multi-angle operation environment presentation for a remote operator, resolve a problem of a visual blind area, and greatly improve safety of the operation. In this solution, a large number of 360-degree cameras do not may be mounted on the vehicle, and only a lightweight MEC may be deployed on the vehicle. For large-scale vehicle remote control, vehicle refitting costs and complexity of project implementation may be greatly reduced.

The disclosure not only may be applied to remote driving of a 5G vehicle, and but also may be widely applied to remote control of a device in the Industrial Internet, including control of an excavator in a scene such as a mine, a rubber tyred gantry crane in a scene such as a port, a mechanical device in industrial manufacturing, or the like.

A method for implementing a 5G remote driving product based on a real-time digital twin is proposed. The 5G network plays an important role in a scene of the Industrial Internet, which is configured to support real-time transmission of network data. The vehicle remote driving product based on the 5G network allows the staff member to remotely control a vehicle while sitting in a simulated cockpit in an office building, which reduces labor intensity of workers in a park, a port, a mine, and another difficult operating condition, and allows the worker to remotely control operation of various vehicles such as a taxi, a truck, a mining truck, and an excavator while sitting in an office building with good conditions. In the remote driving solution for the vehicle, a camera having a plurality of perspectives may be installed on the vehicle, and the MEC is deployed on the vehicle to complete acquisition and transmission of an uplink video and traveling state data and transmission of a downlink vehicle control instruction. Due to a large amount of video transmission, a relatively high requirement is imposed on an uplink bandwidth of the 5G network. In addition, at night or in severe weather such as rain, snow, and smog, the video cannot effectively identify a traffic status, resulting in impracticability of the remote driving. A 5G remote driving solution based on a real-time digital twin is implemented through the disclosure. A perceptual computing service is deployed on a roadside to perform analysis and calculation for a traffic status and an environment in real time. Then roadside perception data is transmitted to a cockpit in an office through a low-latency 5G network. However, a cockpit side renders and presents a panoramic driving state and the traffic status and environment of a current vehicle based on the real-time digital twin technology, so that a staff member is allowed to perform remote driving around the clock. Moreover, the digital twin can present a 360-degree road operation scene in real time, safety of the remote driving may be further improved. In addition, a vehicle camera is no longer relied on to perform an acquisition operation, but to perform a real-time calculation and report structured traffic status data through a sensor device and the MEC deployed on the roadside. Only the lightweight MEC may be deployed on the vehicle, which is only configured for transmission of an uplink vehicle state and a downlink vehicle control command. In terms of implementation, the camera does not may be mounted on the vehicle, complex video acquisition and transmission do not may be performed, and the roadside sensor device and the MEC are shared by all vehicles, thereby reducing complexity and costs of the entire solution.

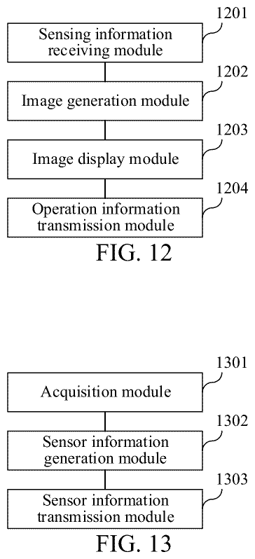

FIG. 12 is a block diagram of a vehicle control apparatus according to some embodiments. The apparatus may be configured to perform all or part of the operations performed by the remote control device in the method shown in FIG. 3 to FIG. 7. As shown in FIG. 12, the apparatus includes:
a sensor information receiving module 1201, configured to receive road sensor information reported by at least one roadside sensor when a target vehicle is on a road, the at least one roadside sensor being arranged along the road;
an image generation module 1202, configured to generate, based on the road sensor information reported by the at least one roadside sensor, a scene image of a scene in which the target vehicle is located;
an image display module 1203, configured to display the scene image through a display screen corresponding to a driving simulator; and
an operation information transmission module 1204, configured to transmit the driving control operation information to the target vehicle, to cause the target vehicle to travel based on the driving control operation information, the driving control operation information being configured for indicating a driving control operation received by the driving simulator.

In some embodiments, the roadside sensor is a sensor device, the road sensor information being generated based on sensor data acquired by the roadside sensor, the sensor data including at least one of image data or radar point cloud data.

In some embodiments, in some embodiments, the image generation module 1202 is configured to: determine, from the road sensor information reported by the at least one roadside sensor, sensor information related to the target vehicle; and generate, based on the sensor information related to the target vehicle, the scene image of the scene in which the target vehicle is located.

In some embodiments, the apparatus further includes: a traveling state information receiving module, configured to receive the traveling state information reported by the target vehicle, the traveling state information including the vehicle position information of the target vehicle; and
an image generation module 1202, configured to screen, based on the vehicle position information, the road sensor information reported by the at least one roadside sensor, to obtain the sensor information related to the vehicle.

In some embodiments, the road sensor information includes identification information of a candidate vehicle within a specified range around the roadside sensor, the candidate vehicle being a vehicle that supports remote control. The image generation module 1202 is further configured to screen, for road sensor information including identification information of the target vehicle, the road sensor information reported by the at least one roadside sensor, to obtain the sensor information related to the vehicle.

In some embodiments, the image generation module 1202 is further configured to: obtain a specified perspective; and generate, based on the specified perspective and the road sensor information reported by the at least one roadside sensor, a scene image of the scene in which the target vehicle is located from the specified perspective.

In some embodiments, the specified perspective includes at least one of a driver's seat perspective or an external perspective, and the external perspective includes at least one of a third-person perspective and a top-down perspective.

In some embodiments, the apparatus further includes a perspective adjustment module, configured to: obtain an adjusted perspective obtained by adjusting the specified perspective by the driving simulator, the adjustment being triggered by the driving simulator in response to a perspective adjustment operation; and generate, based on the adjusted perspective and the road sensor information reported by the at least one roadside sensor, a scene image of the scene in which the target vehicle is located under the adjusted perspective; and

The image display module 1203 is further configured to display the scene image under the adjusted perspective on the display screen.

FIG. 13 is a block diagram of a vehicle control apparatus according to some embodiments. The apparatus may be configured to perform all or part of the operations performed by the roadside sensor in the method shown in FIG. 3 to FIG. 7. As shown in FIG. 13, the apparatus includes:
an acquisition module 1301, configured to acquire sensor data for a road;
a sensor information generation module 1302, configured to generate road sensor information of the roadside sensor based on the sensor data; and
a sensor information transmission module 1303, configured to report the road sensor information to a remote control device.

The remote control device is configured to: generate, based on road sensor information reported by at least one roadside sensor, a scene image of a scene in which the target vehicle is located, display the scene image through a display screen corresponding to a driving simulator, obtain driving control operation information generated by the driving simulator in response to a driving control operation, and transmit the driving control operation information to the target vehicle, the driving control operation information being configured for instructing the target vehicle to travel based on the driving control operation information.

In some embodiments, the road sensor information includes identification information of a candidate vehicle within a specified range around the roadside sensor, the candidate vehicle being a vehicle that supports remote control.

In some embodiments, the remote control device is further configured to: screen, for road sensor information including identification information of the target vehicle, the road sensor information reported by the at least one roadside sensor, to obtain the sensor information related to the target vehicle, and generate, based on the sensor information related to the target vehicle, the scene image of the scene in which the target vehicle is located.

In some embodiments, the sensor information generation module 1102 is configured to perform fusion perception calculation based on the sensor data, to obtain structured road sensor information.

The structured road sensor information includes a road surface object on the road and object information of the road surface object,
the road surface object including at least one of a vehicle, a pedestrian, and a road facility, and the object information including at least one of a position, a speed, and a moving direction.

According to some embodiments, each module may exist respectively or be combined into one or more modules. Some modules may be further split into multiple smaller function subunits, thereby implementing the same operations without affecting the technical effects of some embodiments. The modules are divided based on logical functions. In actual applications, a function of one module may be realized by multiple modules, or functions of multiple modules may be realized by one module. In some embodiments, the apparatus may further include other modules. In actual applications, these functions may also be realized cooperatively by the other modules, and may be realized cooperatively by multiple modules.

A person skilled in the art would understand that these “modules” could be implemented by hardware logic, a processor or processors executing computer software code, or a combination of both. The “modules” may also be implemented in software stored in a memory of a computer or a non-transitory computer-readable medium, where the instructions of each module are executable by a processor to thereby cause the processor to perform the respective operations of the corresponding module.

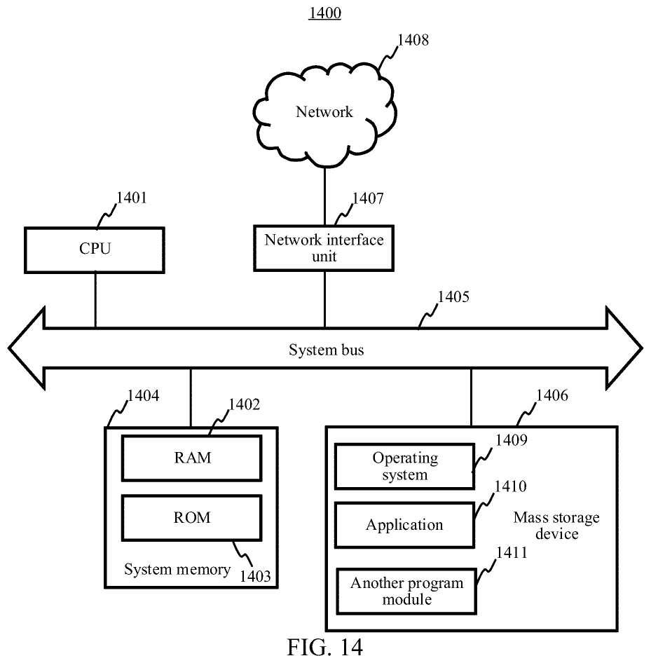

FIG. 14 is a structural block diagram of a computer device 1400 according to some embodiments. The computer device can be implemented as the server in some embodiments of the disclosure. The computer device 1400 includes a central processing unit (CPU) 1401, a system memory 1404 including a random access memory (RAM) 1402 and a read-only memory (ROM) 1403, and a system bus 1405 connecting the system memory 1404 to the CPU 1401. The computer device 1400 further includes a mass storage device 1406 configured to store an operating system 1409, an application 1410, and another program module 1411.

The mass storage device 1406 is connected to the CPU 1401 by using a mass storage controller connected to the system bus 1405. The mass storage device 1406 and an associated computer-readable medium provide non-volatile storage for the computer device 1400. In other words, the mass storage device 1406 may include a computer-readable medium such as a hard disk or a compact disc read-only memory (CD-ROM) drive.

The computer-readable medium may include a computer storage medium and a communication medium. The computer storage medium includes volatile and non-volatile media, and removable and non-removable media implemented by using any method or technology configured for storing information such as computer-readable instructions, data structures, program modules, or other data. The computer storage medium includes a RAM, a ROM, an erasable programmable ROM (EPROM), an electrically-erasable programmable ROM (EEPROM), a flash memory or another solid-state memory technology, a CD-ROM, a digital versatile disc (DVD) or another optical memory, a magnetic cassette, a magnetic tape, a magnetic disk memory, or another magnetic storage device. Certainly, a person skilled in art can know that the computer storage medium is not limited to the foregoing several types. The foregoing system memory 1404 and the mass storage device 1406 may be collectively referred to as a memory.

According to the embodiments of the present disclosure, the computer device 1400 may further be connected, through a network such as the Internet, to a remote computer on the network and run. In other words, the computer device 1400 may be connected to a network 1408 through a network interface unit 1407 connected to the system bus 1405, or may be connected to other types of networks or remote computer systems through the network interface unit 1407.

The memory further includes at least one computer-readable instruction. The at least one computer-readable instruction is stored in the memory. The central processor 1401 executes the at least one computer-readable instruction to implement all or part of the operations in the method shown in the foregoing embodiments.

In an exemplary embodiment, a computer-readable storage medium is further provided, which is configured to store at least one computer-readable instruction. The at least one computer-readable instruction is loaded and executed by a processor to implement all or part of the operations in the method shown in the foregoing embodiments. For example, the computer-readable storage medium may be a ROM, a RAM, a compact disc ROM (CD-ROM), a magnetic tape, a floppy disk, an optical data storage device, or the like.

In an exemplary embodiment, a computer program product or a computer-readable instruction is further provided. The computer program product or the computer-readable instruction includes a computer instruction. The computer instruction is stored in a computer-readable storage medium. The processor of the computer device reads the computer instruction from the computer-readable storage medium. The processor executes the computer instruction, so that the computer device performs all or part of the operations in the method shown in the foregoing embodiments.

After considering the disclosure, a person skilled in the art may conceive of other embodiments. The disclosure is intended to cover any variations, uses, or adaptive changes of the disclosure. These variations, uses, or adaptive changes follow the principles of the disclosure and include common knowledge or common technical means in the art. The foregoing embodiments are considered as merely exemplary.

The scope of the disclosure is not limited to the precise structures described above and shown in the drawings, and various modifications and changes may be made without departing from the spirit of the disclosure.

Technical features of the foregoing embodiments may be combined in different manners to form other embodiments. To make description concise, not all possible combinations of the technical features in the foregoing embodiments are described. However, the combinations of these technical features shall be considered as falling within the scope of the disclosure.

The foregoing embodiments are used for describing, instead of limiting the technical solutions of the disclosure. A person of ordinary skill in the art shall understand that although the disclosure has been described in detail with reference to the foregoing embodiments, modifications can be made to the technical solutions described in the foregoing embodiments, or equivalent replacements can be made to some technical features in the technical solutions, provided that such modifications or replacements do not cause the essence of corresponding technical solutions to depart from the spirit and scope of the technical solutions of the embodiments of the disclosure and the appended claims.

What is claimed is:

1. A vehicle control method, performed by a remote control system, comprising:
receiving road sensor information transmitted from at least one roadside sensor when a target vehicle is on a road;
generating, based on the road sensor information, a scene image depicting a scene in which the target vehicle is located;
displaying the scene image through a display screen corresponding to a driving simulator;
obtaining driving control operation information generated by the driving simulator in response to a driving control operation, the driving control operation information providing traveling instructions based on the driving control operation information for the target vehicle; and
transmitting the driving control operation information to the target vehicle.

2. The vehicle control method according to claim 1, wherein the road sensor information is based on sensor data comprising at least one of image data or radar point cloud data.

3. The vehicle control method according to claim 1, wherein the generating the scene image comprises:
determining, based on the road sensor information, first sensor information related to the target vehicle; and
generating, based on the first sensor information, the scene image.

4. The vehicle control method according to claim 3, further comprising receiving vehicle position information reported by the target vehicle,
wherein the determining the first sensor information comprises screening, based on the vehicle position information, the road sensor information, to obtain the first sensor information.

5. The vehicle control method according to claim 3, wherein the road sensor information comprises identification information of a candidate vehicle supporting remote control within a predetermined range from the at least one roadside sensor, and
wherein the determining, the first sensor information comprises obtaining the first sensor information by screening the road sensor information for the identification information.

6. The vehicle control method according to claim 1, wherein the generating the scene image comprises:
obtaining perspective information; and
generating, based on the perspective information and the road sensor information, the scene image from the a perspective corresponding to the perspective information.

7. The vehicle control method according to claim 6, wherein the perspective corresponds to one from among a plurality of perspectives,
wherein the plurality of perspectives comprise at least one of a driver's seat perspective or one or more external perspectives, and
wherein the one or more external perspectives comprise at least one of a third-person perspective and a top-down perspective.

8. The vehicle control method according to claim 6, further comprising:
obtaining adjusted perspective information from the driving simulator based on a perspective adjustment operation; and
generating, based on the adjusted perspective information and the road sensor information, the scene image from the adjusted perspective.

9. The vehicle control method according to claim 1, wherein the scene image is a three-dimensional image.

10. The vehicle control method according to claim 1, wherein the target vehicle is taxi, a truck, a mining truck, an excavator, or a gantry crane.

11. A vehicle control apparatus, the vehicle control apparatus comprising:
at least one memory configured to store computer program code; and
at least one processor configured to read the program code and operate as instructed by the program code, the program code comprising:
sensor information receiving code configured to cause at least one of the at least one processor to receive road sensor information transmitted from at least one roadside sensor when a target vehicle is on a road;
image generation code configured to cause at least one of the at least one processor to generate, based on the road sensor information, a scene image depicting a scene in which the target vehicle is located;
image display code configured to cause at least one of the at least one processor to display the scene image through a display screen corresponding to a driving simulator;
operation information code configured to cause at least one of the at least one processor to obtain driving control operation information generated by the driving simulator in response to a driving control operation, the driving control operation information providing traveling instructions based on the driving control operation information for the target vehicle; and
transmission code configured to cause at least one of the at least one processor to transmit the driving control operation information to the target vehicle.

12. The vehicle control apparatus according to claim 11, wherein the road sensor information is based on sensor data comprising at least one of image data or radar point cloud data.

13. The vehicle control apparatus according to claim 11, wherein the image generation code further comprises target vehicle determination code configured to cause at least one of the at least one processor to determine, based on the road sensor information, first sensor information related to the target vehicle, and
wherein the image generation code is configured to cause at least one of the at least one processor to generate, based on the first sensor information, the scene image.

14. The vehicle control apparatus according to claim 13, wherein the program code further comprises vehicle position code configured to cause at least one of the at least one processor to receive vehicle position information reported by the target vehicle, and
wherein the target vehicle determination code is configured to cause at least one of the at least one processor to screen, based on the vehicle position information, the road sensor information, to obtain the first sensor information.

15. The vehicle control apparatus according to claim 13, wherein the road sensor information comprises identification information of a candidate vehicle supporting remote control within a predetermined range from the at least one roadside sensor, and
wherein the target vehicle determination code is configured to cause at least one of the at least one processor to obtain the first sensor information by screening the road sensor information for the identification information.

16. The vehicle control apparatus according to claim 11, wherein the image generation code further comprises perspective code configured to cause at least one of the at least one processor to obtain perspective information, and
wherein the image generation code is configured to generate, based on the perspective information and the road sensor information, the scene image from the a perspective corresponding to the perspective information.

17. The vehicle control apparatus according to claim 16, wherein the perspective corresponds to one from among a plurality of perspectives,
wherein the plurality of perspectives comprise at least one of a driver's seat perspective or one or more external perspectives, and
wherein the one or more external perspectives comprise at least one of a third-person perspective and a top-down perspective.

18. The vehicle control apparatus according to claim 16, wherein the image generation code further comprises adjusted perspective code configured to cause at least one of the at least one processor to obtain adjusted perspective information from the driving simulator based on a perspective adjustment operation, and
wherein the image generation code is configured to cause at least one of the at least one processor to generate, based on the adjusted perspective information and the road sensor information, the scene image from the adjusted perspective.

19. The vehicle control apparatus according to claim 11, wherein the scene image is a three-dimensional image.

20. A non-transitory computer-readable storage medium, storing computer code which, when executed by at least one processor, causes the at least one processor to at least:
receive road sensor information transmitted from at least one roadside sensor when a target vehicle is on a road;
generate, based on the road sensor information, a scene image depicting a scene in which the target vehicle is located;
display the scene image through a display screen corresponding to a driving simulator;
obtain driving control operation information generated by the driving simulator in response to a driving control operation, the driving control operation information providing traveling instructions based on the driving control operation information for the target vehicle; and
transmit the driving control operation information to the target vehicle.
